(19) United States
(12) Patent Application Publication
(10) Pub. No.: US 2026/0328618 A1
(43) Pub. Date: Oct. 22, 2026

(54) MINIATURIZED SPECTROMETER WITH A TUNABLE VAN DER WAALS JUNCTION

(71) Applicant: Aalto University Foundation sr, Aalto (FI)

(72) Inventors: Faisal Ahmed, Aalto (FI); Zhipei Sun, Aalto (FI); Hoon Hahn Yoon, Aalto (FI)

(21) Appl. No.: 19/104,717

(22) PCT Filed: Aug. 25, 2023
(86) PCT No.: PCT/FI2023/050483

§ 371 Date: Feb. 19, 2025

(30) Foreign Application Priority Data
Aug. 25, 2022 (FI) 20227114

(51) Int. Cl. G01J 3/28; G01J 3/02

(52) U.S. Cl. CPC G01J 3/28; G01J 3/0256

(57) ABSTRACT

According to an example aspect of the present invention, there is provided a spectrometer comprising a layer of molybdenum disulphide and a layer of tungsten diselenide forming a van der Waals heterojunction therebetween, a hexagonal form boron nitride layer facing the layer of tungsten diselenide and a part of the layer of molybdenum disulphide, a second hexagonal form boron nitride layer covering the layers of molybdenum disulphide and tungsten diselenide, a monolayer graphene film, facing the hexagonal boron nitride layer, and an electrical connection, provided with a tunable gate-source voltage source, connecting the monolayer graphene film and the layer of molybdenum disulphide.

### FIELD

The present disclosure relates to the field of spectrometry.

### BACKGROUND

Miniaturized computational spectrometers, which can obtain incident spectra using a combination of device spectral response and reconstruction algorithm, are essential for on-chip and implantable applications. Highly-sensitive spectral measurement using only a single detector holds the key to future advancements to significantly scale down footprints of such spectrometers while allowing spectral resolution approaching that of benchtop systems.

### SUMMARY

According to some aspects, there is provided the subject-matter of the independent claims. Some embodiments are defined in the dependent claims.

According to a first aspect of the present disclosure, there is provided a spectrometer comprising a layer of molybdenum disulphide and a layer of tungsten diselenide forming a van der Waals heterojunction therebetween, a hexagonal form boron nitride layer facing the layer of tungsten diselenide and a part of the layer of molybdenum disulphide, a second hexagonal form boron nitride layer covering the layers of molybdenum disulphide and tungsten diselenide, a monolayer graphene film, facing the hexagonal boron nitride layer, and an electrical connection, provided with a tunable gate-source voltage source, connecting the monolayer graphene film and the layer of molybdenum disulphide.

### BRIEF DESCRIPTION OF THE DRAWINGS

FIG. 1: Ultra-miniaturized spectrometer concept with a single-vdW-junction. A, A typical gate-tunable band alignment at the vdW junction interface (upper) with its distinct gate tunable spectral response matrix (lower). E_{C} (E_{V}) represents the conduction (valence) band edge. B, Schematic diagram of various application examples using our single-junction spectrometer: wavelength meter to distinguish peak wavelengths of monochromatic light (upper), spectrometer to resolve broadband spectra (middle), and spectral imager to analyze spectral information of images (lower).

FIG. 2: Single-junction spectrometer demonstration. A, Schematic of our MoS₂/WSe₂ heterojunction spectrometer (left) and its optical images on the h-BN and graphene layers before (middle) and after (right) depositing electrodes and stacking the top h-BN passivation layer. The top h-BN layer is not presented in the upper panel for better visibility. B and C, Transfer curves of the MoS₂ and WSe₂ channels and their heterojunction with the graphene gate without (B) and with (C) light illumination at different wavelengths with a fixed power of ~20 μW. D, Color contour plots of the spectral response matrix. E and F, Quasi-monochromatic (E, bandwidth: ~10 nm), two different broadband (F) spectra reconstructed with our spectrometer (solid) and measured using a commercial spectrometer (dashed). G, Peak signal-to-noise ratio between reconstructed and reference spectra as a function of learning step.

FIG. 3: High-performance wavelength resolving power and spectral resolution. A, Color contour plot of the high-density spectral response matrix with a learning step of ~0.1 nm. B, Monochromatic (bandwidth: ~2 nm) spectra reconstructed with our spectrometer (solid) and measured using a commercial spectrometer (dashed). C, Peak wavelengths of the reconstructed and measured spectra as a function of input wavelength. D, Peak wavelength difference between reconstructed and reference spectra (upper panel), and wavelength resolving power of our single-junction spectrometer (lower panel). E, Complex spectra reconstructed (solid) and measured (dashed). F, Future prospect of our single junction spectrometer aiming for ultrahigh-resolution.

FIG. 4: Proof-of-concept demonstration of spectral imaging. A, Configuration of spectral imaging using our single-junction spectrometer with a spatial scanning method. A broadband light source filtered with a color image is incident to our spectrometer for spectral imaging. B, Photocurrent mapping data scanned at different V_{GS}. C, Spectral images reconstructed at different wavelengths, covering the visible to near-infrared ranges. Higher intensity at each wavelength indicates more broadband light is transmitted through the color image. The pixel intensity in B and C is normalized with each maximum intensity.

FIG. 5: Spectrometer miniaturization. A historical perspective on major miniaturization strategies (1-11, 39-41). (Left) A typical traditional spectrometer including bulky dispersive optics and an array of thousands of detectors (1, 2). (Middle) State-of-the-art spectrometers with minimized optical elements or reduced detectors (3-8, 39-41). (Right) A miniaturized single-detector spectrometer using a tunable spectral detector (9-11). In this work, we utilize a single vdW junction for interlayer transport mediated spectral response engineering.

FIG. 6: Summarized workflow diagram. A, Simplified version. B, Detailed version. As shown in the diagram, a computational method is required to reconstruct the unknown spectra by solving a constrained least square solution with the adaptive Tikhonov regularization (1, 8). Based on the spectral response matrix encoded during the learning process and advanced reconstruction algorithm, incident light with an unknown spectral information measured during the testing process can be computationally obtained from the photocurrent data measured with our single-vdW-junction spectrometer.

FIG. 7: Optical and structural characterization of single-junction spectrometer. h-BN/MoS₂/WSe₂/h-BN/graphene heterostructure characterized with the optical microscope, atomic force microscopy (AFM) using the tapping mode, and Raman spectroscopy equipped with a 532 nm continuous wave laser. The bright-field (A) and dark-field (B) optical microscopy images confirm the absence of scattered light near the heterojunction and individual channel, indicating the surface morphology free from defects or wrinkles. The thicknesses of the top h-BN, MoS₂, WSe₂, bottom h-BN flakes, measured by AFM (C and D), were ~19, 28, 33, and 53 nm, respectively. The Raman intensity mapping images (E, F, G, and H) of the MoS₂, WSe₂, graphene, and h-BN flakes were reconstructed with A_{1g}, E¹_{2g}, 2D, and E_{2g} peaks, respectively. The corresponding Raman spectra are shown in I and J.

FIG. 8: Electrical characterization of spectrometer devices. Gate-tunable output curves of individual MoS₂ (A), WSe₂ (B) channels, and their heterojunction (C).

FIG. 9: Rectifying ratio and diode ideality factor. Rectification ratio (upper,

$$\frac{{I}_{DS , F}}{{I}_{DS , R}} )$$

and ideality factor (lower,

$$\frac{q}{kT} \frac{{dV}_{DS}}{{dI}_{DS}} )$$

of the MoS₂/WSe₂ heterojunction, where I_{DS,F} and I_{DS,R} are the drain-source current I_{DS} at drain-source voltage V_{DS}=3 and −3 V, respectively, q is the electronic charge, and T is the absolute temperature. The rectifying behavior at different V_{GS} is determined by the competition between tunneling and recombination (22-28).

FIG. 10: Fowler-Nordheim plot analysis. a,b, Fowler-Nordheim (FN) tunneling plots (50) for the MoS₂/WSe₂ heterojunction at V_{DS}>0 (A) and V_{DS}<0 (B). The colored areas indicate the range of V_{DS} where FN tunneling occurs. Each plot shows that the transition point of the charge carrier transport mechanism from direct tunneling to FN tunneling is gate-tunable.

FIG. 11: Bias-dependent band alignment and carrier transport mechanism. Tunable MoS₂/WSe₂ heterojunction with an inversion layer that involves tunneling and recombination of free carriers (22-28).

FIG. 12: Power-dependent spectral response matrix. Transfer curves of the MoS₂/WSe₂ heterojunction with the graphene gate at V_{DS}=3 V under light illumination at different powers and wavelengths. The corresponding color contour plot of the power-dependent gate-tunable spectral response of the MoS₂/WSe₂ heterojunction. (A,E) 4 μW, (B,F) 20 μW, (C,G) 100 μW, and (D,H) 500 μW.

FIG. 13: Gate-tunable charge carrier transport mechanism in dark condition or under light illumination. A, Transfer curves of the MoS₂/WSe₂ heterojunction with the graphene gate at V_{DS}=3 V in dark condition. The ranges of V_{GS} for different charge carrier transport mechanisms (Cases A, B, and C) are indicated by the red, green, and blue areas. B, C, and D, Dynamics of charge carrier across the gate-tunable MoS₂/WSe₂ heterointerface. (22-28) E, Color contour plot of the spectral response matrix depending on V_{GS} and incident light wavelengths with a fixed power of 20 μW. The boundaries of each case shown in A are marked with black dashed lines. F, G, and H, Dynamics of photoexcited charge carrier generated across the gate-tunable MoS₂/WSe₂ heterointerface. (22-28) Case A (B and F): The staggered band gap induced by the negative V_{GS} blocks the electrons from MoS₂ to the conduction band of WSe₂ and holes from WSe₂ to the valence band of MoS₂. The dark current corresponds to the interlayer recombination of MoS₂ electrons and WSe₂ holes. The interlayer recombination is limited by the supply of electrons from MoS₂. Thus, light absorbed by MoS₂ leading to the photogenerated electrons in MoS₂ dominates the photoresponse. Case B (C and G): The dark current is mainly due to the interlayer recombination of MoS₂ electrons and WSe₂ holes. The interlayer recombination is limited by the supply of holes from WSe₂. Light absorbed by WSe₂ leads to photogenerated holes in the WSe₂ which dominate the photoresponse. Case C (D and H): The positive V_{GS} reduces the energy of the WSe₂ band edge, altering the staggered band gap. (27, 28) The energy of the MoS₂ band edge is less sensitive to the V_{GS} due to the high density of states at the MoS₂ Fermi level. (61-63) The dark current is dominated by the flow of electrons from MoS₂ to WSe₂. The photocurrent is dominated by the tunneling of both electrons excited from MoS₂ to WSe₂ and holes excited from WSe₂ to MoS₂. Thus, the photoresponse is sensitive to light absorption in both materials.

FIG. 14: Gate-tunable photovoltaic effect. Photovoltaic effect across the MoS₂/WSe₂ heterojunction. (22-28) The short-circuit current, zero-voltage current, open-circuit voltage, and zero-current voltage are obtained at different V_{GS} in dark or under light illumination of wavelengths at ~550 and 750 nm. The photovoltaic effect confirms the spectral detection performance with giant gate-tunability. (37, 38)

FIG. 15: Photo-switching characteristics. A and B, measured photocurrent of the MoS₂/WSe₂ heterojunction as a function of time with the silicon gate (A) or graphene gate (B) under the illumination of a 532 nm laser switched on/off every ~5 secs. The photocurrent gradually decreases with the silicon gate, causing an error with time, whereas the photocurrent is measured to be almost constant with the graphene gate regardless of time, ensuring stable and fast encoding of the spectral response matrix during the learning process.

FIG. 16: Wavelength-dependent photoresponse mechanisms. A, Spectral response of the MoS₂/WSe₂ heterojunction at different V_{GS}. The distinct photoresponse at 750 nm corresponds to the exciton absorption resonance of WSe₂. The 750-nm feature appears at positive V_{GS}, when WSe₂ is undoped, but disappears at negative V_{GS}, when WSe₂ is doped with holes. Two mechanisms likely contribute to modulating this feature. First, the exciton oscillator strength is known to be reduced in strongly doped semiconductors due to Pauli blocking and screening of Coulomb interactions. (29, 64, 65) Second, negative V_{GS} changes the band alignment of the staggered gaps and can block photoexcited carriers from through the MoS₂/WSe₂ interface. B, V_{GS} strongly modulates the band energies in WSe₂, but weakly modulates the band energies in MoS₂. There are two reasons for this asymmetry. First, MoS₂ has a larger concentration of dopant impurities due to its sulfur-vacancies, (61-63) which keeps the Fermi-level close to the conduction band edge. On the other hand, due to the Fermi-level pinning-free nature of WSe₂, (61-63) the Fermi level can easily shift to the neutral position within its bandgap, where the exciton absorption increases. Second, MoS₂ is stacked on top of WSe₂, thus WSe₂ screens the gate when WSe₂ is strongly doped. Generation, separation, and extraction of photoexcited charge carriers depends on incident photon energy and V_{GS}. After photoexcited carriers are generated with photon energies larger than E_{g,WSe2} and E_{g,MoS2} (C and E), the extraction of carriers depends on interplay of tunneling and recombination. For example, the photocurrent is dominated by the interlayer recombination of photogenerated electrons (holes) from MoS₂ (WSe₂) in C. In contrast, the photocurrent is dominated by the direct interlayer tunneling of photogenerated electrons (holes) from MoS₂ (WSe₂) in E. Due to the difference in bandgaps, photon energies between E_{g,WSe2} and E_{g,MoS2} are only absorbed by WSe₂ (D and F). Depending on the band alignment, the photocurrent is affected by the direct tunneling of photogenerated holes from WSe₂ into MoS₂.

FIG. 17: Gate-tunable photoresponse using graphene gate compared to silicon gate. Transfer curves of the MoS₂ (A and D) and WSe₂ (B and E) channels and their heterojunction (C and F) with the silicon gate (A, B and C) or graphene gate (D, E and F) at V_{DS}=3 V in dark condition and under light illumination at 532 and 730 nm with a power of W. A schematic of the device structure and electrical configuration is provided in each panel. Corresponding hysteresis window (G) and current (H), that confirms the giant gate-tunability (saturation current level achieved with a small V_{GS}) and low hysteresis window (minimized error of measured current for gate sweep) of the graphene gate (37, 38) compared to the silicon gate.

FIG. 18: Optical setup for spectrometer measurement. Schematic of the optical setup for the comparison of the reconstructed spectra obtained with our single-junction spectrometer and the reference spectra measured with a commercial spectrometer. Note that the wavelength selector represents an individual tool of a tunable wavelength filter, grating monochromator, color filters, or their coupled system to generate the monochromatic or broadband light source used in our measurement.

FIG. 19: Peak wavelength analysis of broadband spectra. Resolving power of our single junction spectrometer that can resolve the peak wavelengths of two broadband spectra close to each other. Two peaks at ~683 nm, separated by ~0.9 nm, are successfully resolved in the green and blue spectra.

FIG. 20: Transmission through color filters. A, Optical setup for a broadband light source and color filters. A broadband light filtered with color filters is incident to our device and the transmission spectrum is acquired with the reconstruction algorithm. B, Reconstructed spectra of transmitted light through color filters.

FIG. 21: Comparison of different miniaturized spectrometers.

FIG. 22 illustrates an example single junction spectrometer capable of supporting at least some embodiments of the present disclosure;

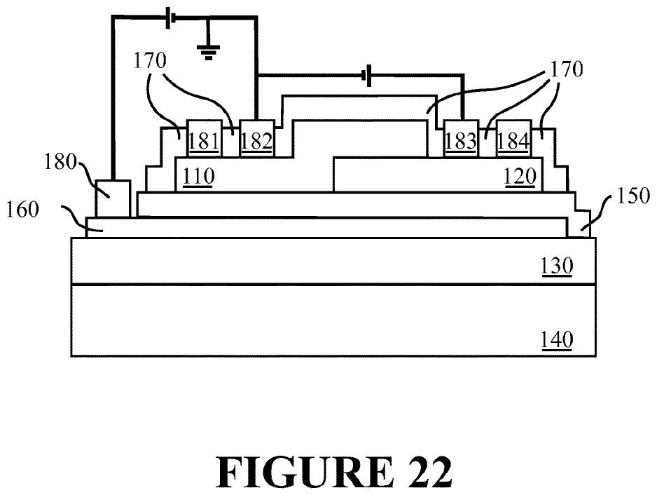

### EMBODIMENTS

We report a high-performance computational spectrometer based on a single van der Waals junction with an electrically-tunable transport-mediated spectral response. We achieve high peak wavelength accuracy (~0.36 nm), high spectral resolution (~3 nm), broad operation bandwidth (from ~405 to 845 nm), and proof-of-concept spectral imaging. Our approach not only defines a new path towards ultra-miniaturization but also offers unprecedented performance in accuracy, resolution, and operation bandwidth for single-detector computational spectrometers.

Spectrometers are indispensable for various applications, including industrial inspection, chemical/biological characterization, and image sensing/analysis (1, 2). Their miniaturization with high spectral resolution and wide operation bandwidth is highly desirable to meet the emerging and future demands in portable and on-chip applications (1). However, conventional spectroscopy systems typically rely on bulky dispersive optical components (e.g., gratings) and detector or filter arrays, which impose strict restrictions on ultra-miniaturization (2).

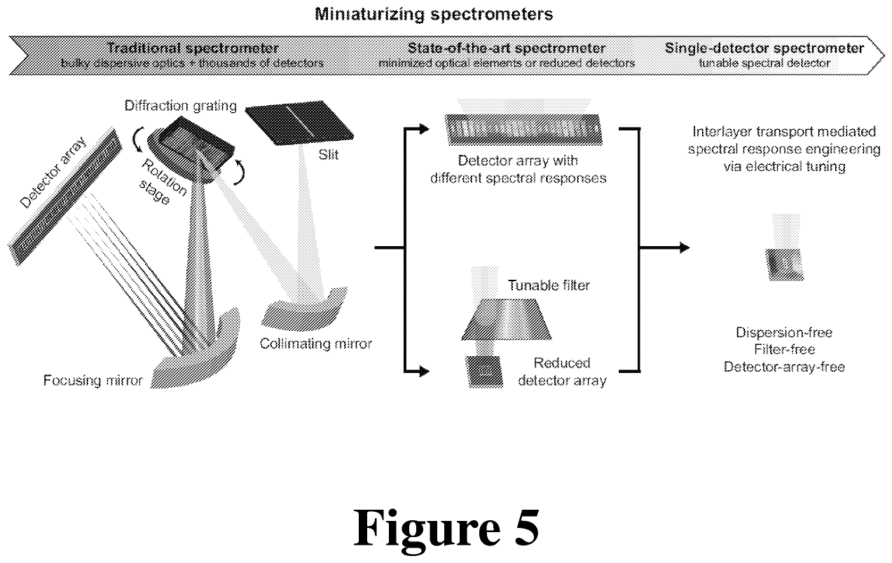

Common spectrometer miniaturization approaches therefore replace the functions of these dispersive optical elements through various schemes (FIG. 5), including photonic crystals (3), metasurfaces (4), and compact interferometers (5). In the past ten years, a profound technological leap has seen the emergence of miniaturized computational spectrometers which leverage the power of mathematical algorithms for spectrum reconstruction (1). Examples of such approaches have elegantly used quantum dot filter arrays on to the charged-coupled device sensor (6), bandgap engineered multiple nanowires (7), a single nanowire with bandgap gradation (8), Stark effect in black phosphorus (9), in situ perovskite modulation (10), and a single superconducting nanowire with tunable quantum efficiency (11). However, the performance and usability of these computational spectrometers are still limited: spectral resolution and operation bandwidth are typically restricted by the number of integrated detectors (6-8), bandgap modulation limits (9, 10), and cryogenic operational requirements (11).

Photodetection with two-dimensional (2D) layered materials is greatly advantageous due to their strong light-matter interaction, atomically-sharp interface, and electrically-tunable photoresponse (12-14). However, insufficient band structure modulation makes it challenging to achieve high-resolution, broadband spectral sensing using a single 2D material. On the other hand, 2D materials-based van der Waals (vdW) junctions offer highly tunable functionalities beyond the constituent materials (15-17) and could overcome these limitations. In particular, we suggest that wavelength-dependent photodetection with vdW junctions recently exploited for optoelectronic logic computing (18, 19) and color sensing (20, 21) could also be key to high-resolution computational spectral sensing.

We establish this hypothesis by demonstrating a high-performance ultra-miniaturized computational spectrometer utilizing a single vdW junction with an electrically-tunable spectral responsivity. Our device, with its footprint defined by the junction size (~22×8 μm²) shows unprecedented performance for a single detector computational spectrometer, with the ability to resolve peak monochromatic wavelengths with ~0.36 nm accuracy, reconstruct broadband spectra with ~3 nm resolution, and acquire spectral images by scanning. Our single-junction spectrometer concept can be extended to other tunable junctions for achieving high spectral resolution and broad operation bandwidth with its ultra-compact size, representing the ultimate miniaturization strategy without sacrificing spectrometer performance.

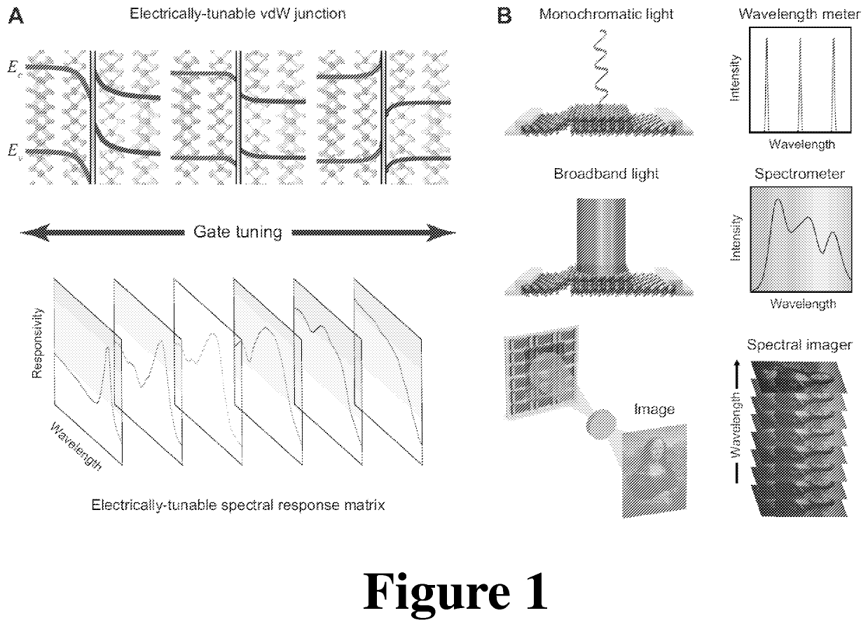

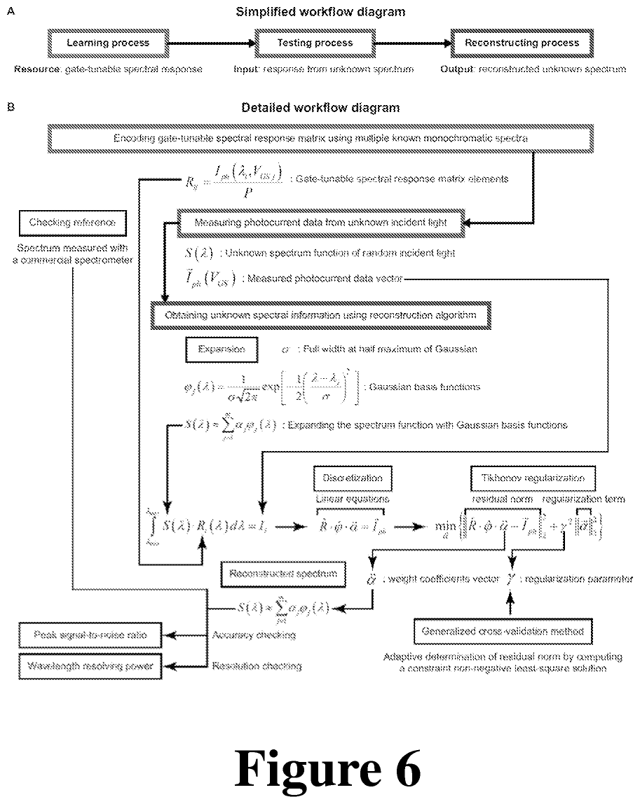

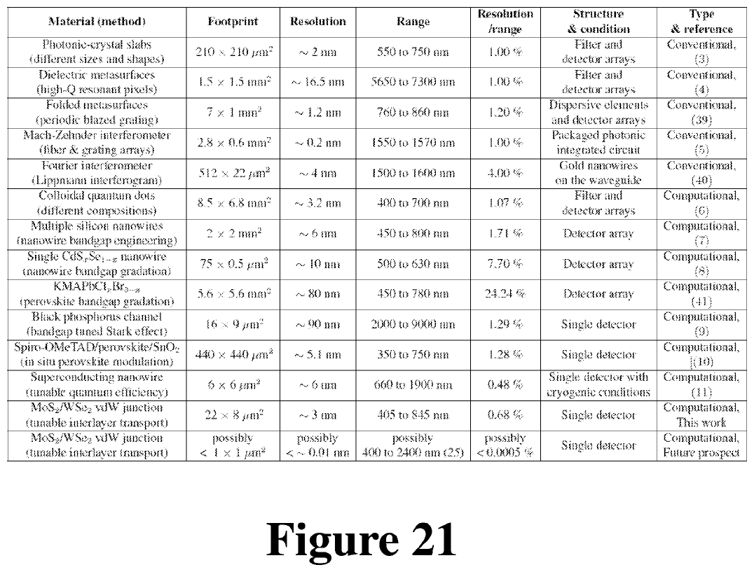

The performance of computational spectrometers relies on the variability of their wavelength dependent photoresponsivity (1, 6-11). The single-detector spectrometers reported thus far are limited by their performance (9, 10) and usability (11) due to the limited band structure modulation and consequently, the spectral response. In contrast, electrical tuning of the interfacial band alignment of a vdW junction (FIG. 1A, upper panel) enables controllable and unique interlayer transport (15-17). This allows a tunable spectral response (FIG. 1A, lower panel) with high sensitivity and variability over a wide spectral range (12-14). This suggests that a single-vdW-junction spectrometer could achieve significantly higher performance than previously reported spectrometers (section ST1 and FIG. 21). We demonstrate this by combining an electrically-tunable single-vdW-junction with computational reconstruction algorithms for various applications (FIG. 1B). To experimentally realize our spectrometer concept, the following three steps are required (FIG. 6): measuring the gate-tunable spectral responses with multiple known incident spectra (learning process); measuring the gate-tunable photocurrent of the unknown incident light to be analyzed (testing process); and computing the spectral information of the unknown incident light based on the results obtained in learning and testing processes with the reconstruction algorithm (reconstructing process).

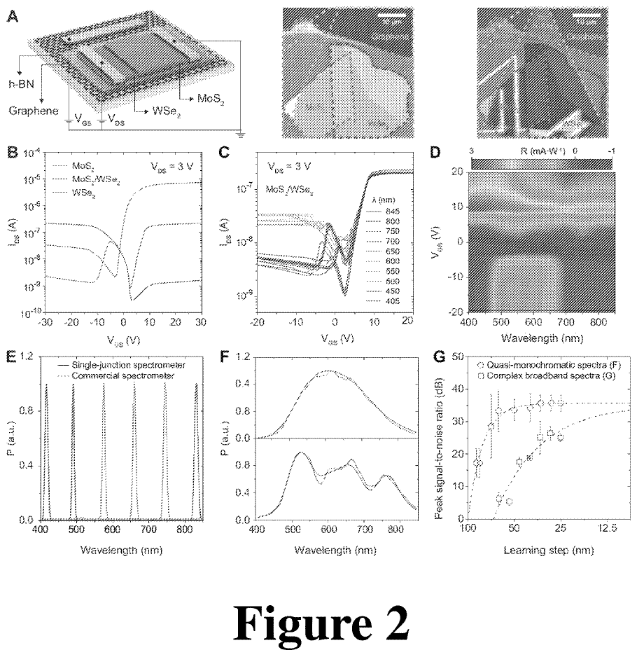

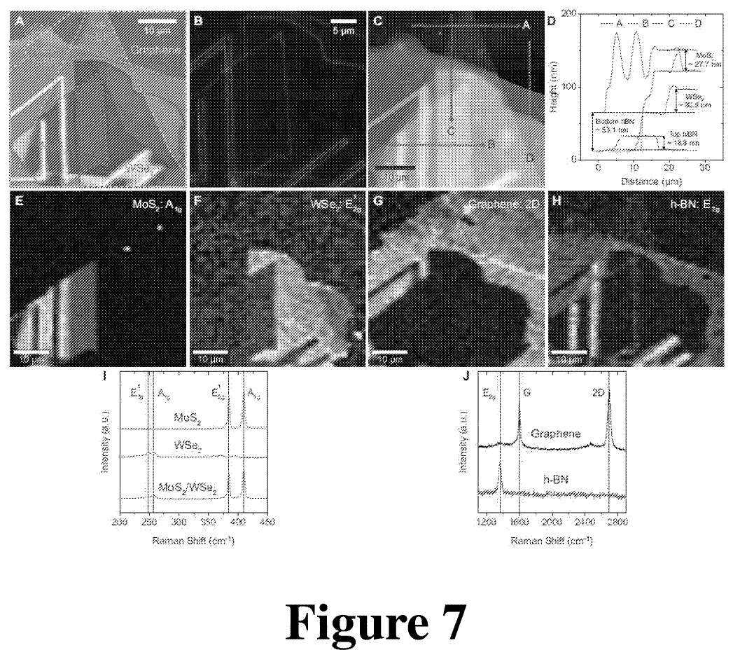

The distinct and varied photoresponse of a vdW junction, tuned at different gate voltages and incident light wavelengths, is critical to our spectrometer miniaturization concept (1). We choose a MoS₂/WSe₂ heterojunction (FIG. 2A) as an example for its distinct spectral response due to the gate-tunable photovoltaic effect from the visible to the near-infrared. (22-28) The MoS₂/WSe₂ heterojunction is encapsulated by top and bottom h-BN layers for insulation and passivation, respectively (section MM1). A monolayer graphene film below the stack is used as a local gate electrode for effective gate tuning. Each stacking layer was characterized by Raman spectroscopy and atomic force microscopy (FIG. 7) to confirm the quality of the vdW heterostructure.

The transfer curves (drain-source current I_{DS} as a function of the gate-source voltage V_{GS}) of the MoS₂ or WSe₂ channels and their heterojunction are measured at drain-source voltage V_{DS}=3 V in dark condition (FIG. 2B). The individual MoS₂ and WSe₂ channels exhibit n(p)− type characteristics due to the donor (acceptor) impurities in MoS₂ (WSe₂). Thus, a depletion region and built-in electric field are expected at their vdW interface (22-28). The MoS₂/WSe₂ heterojunction is characterized by positive V_{DS} applied to the WSe₂ side, corresponding to the forward biasing of the diode. The sign change of transconductance,

$$\frac{{dI}_{DS}}{{dV}_{DS}} ,$$

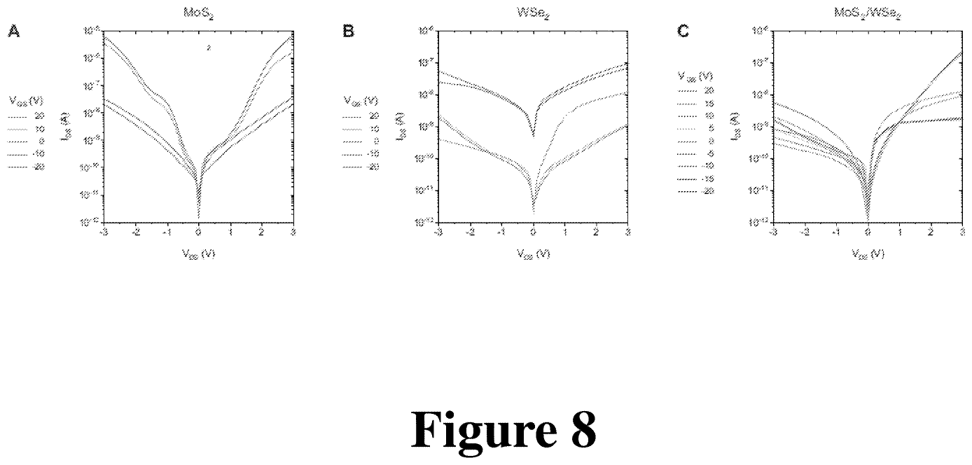

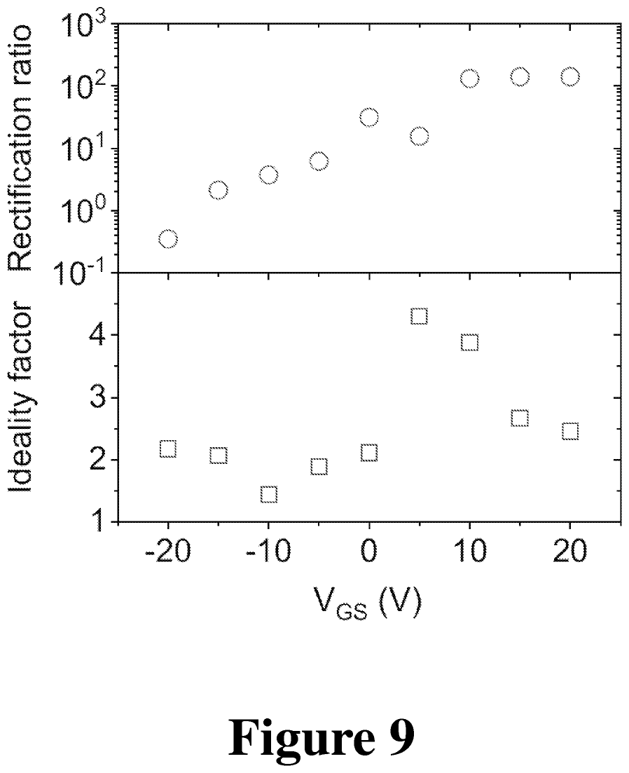

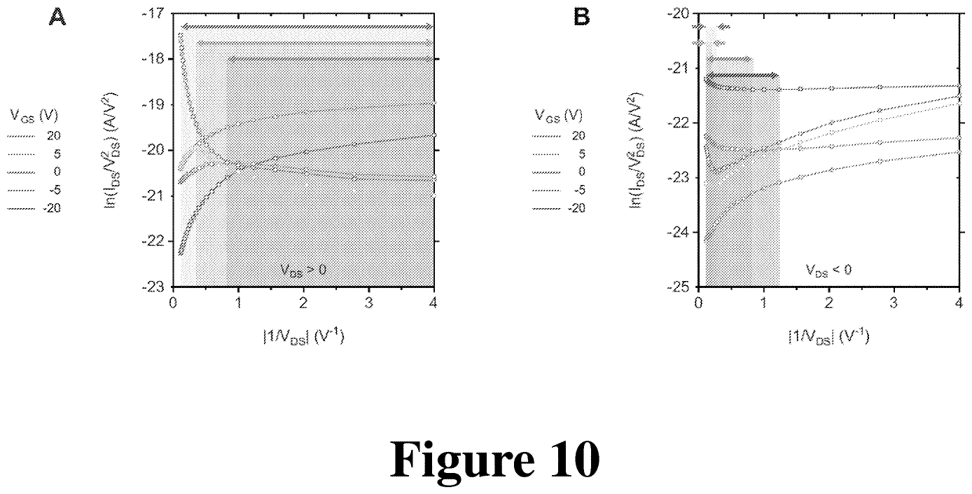

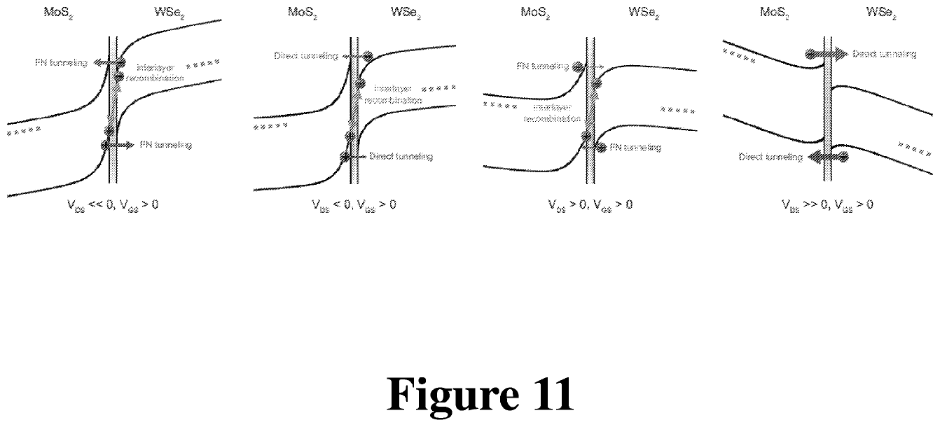

occurs at V_{GS}=~−5 V, matching the hole current from WSe₂ with the electron current from MoS₂. This “anti-ambipolar” behavior and other transport properties (FIGS. 8, 9, 10, and 11) are typical of the MoS₂/WSe₂ heterojunctions (22-28), providing clearly distinguishable V_{GS}-dependence.

The transfer curves of the MoS₂/WSe₂ heterojunction measured under multiple known incident lights with a bandwidth of ~10 nm indicate a strong wavelength dependence (FIG. 2C). The photoresponsivity,

$$R = \frac{{I}_{ph}}{P} ,$$

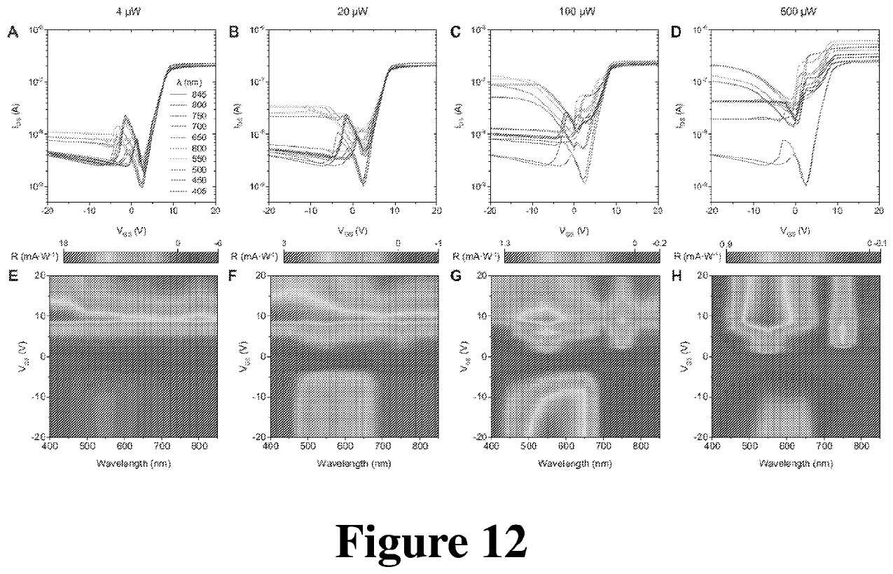

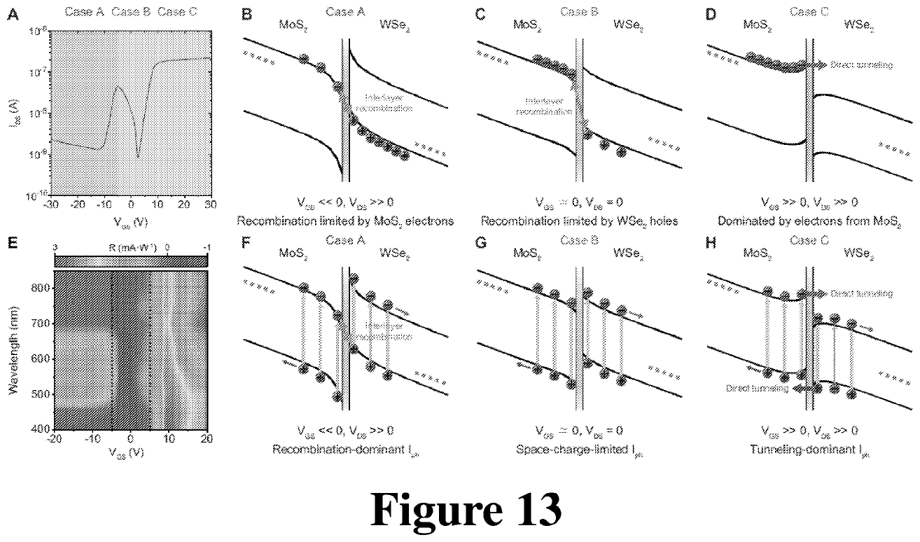

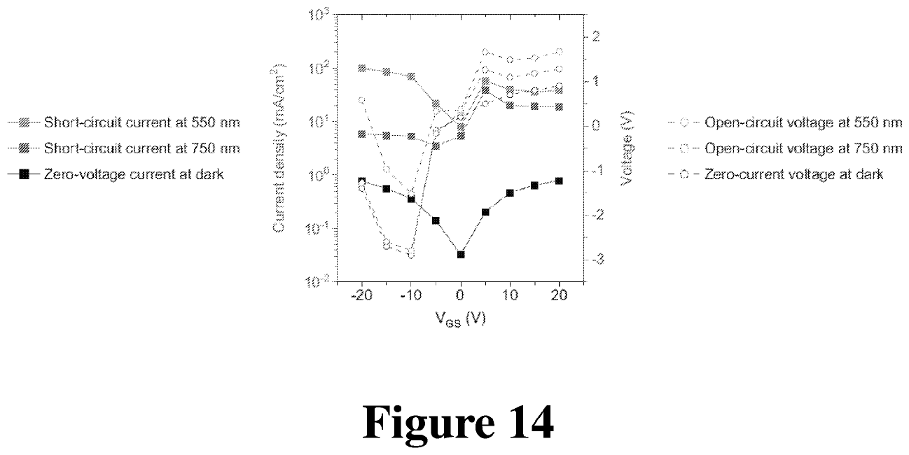

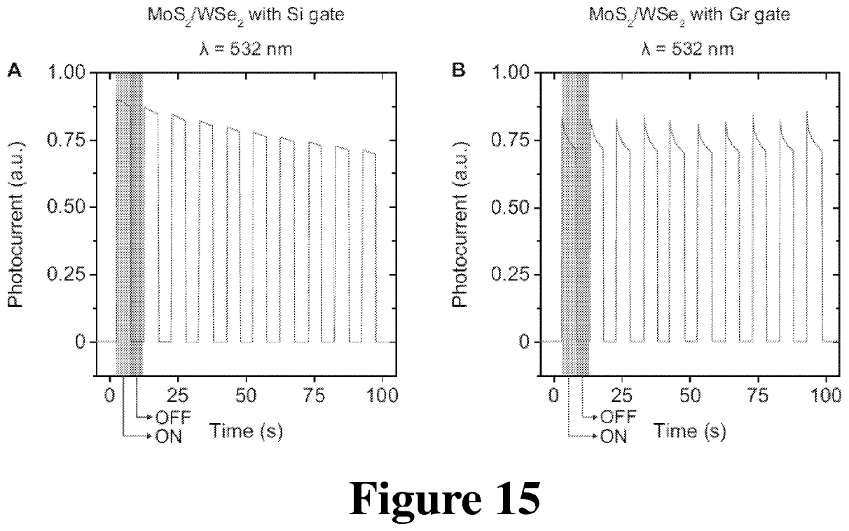

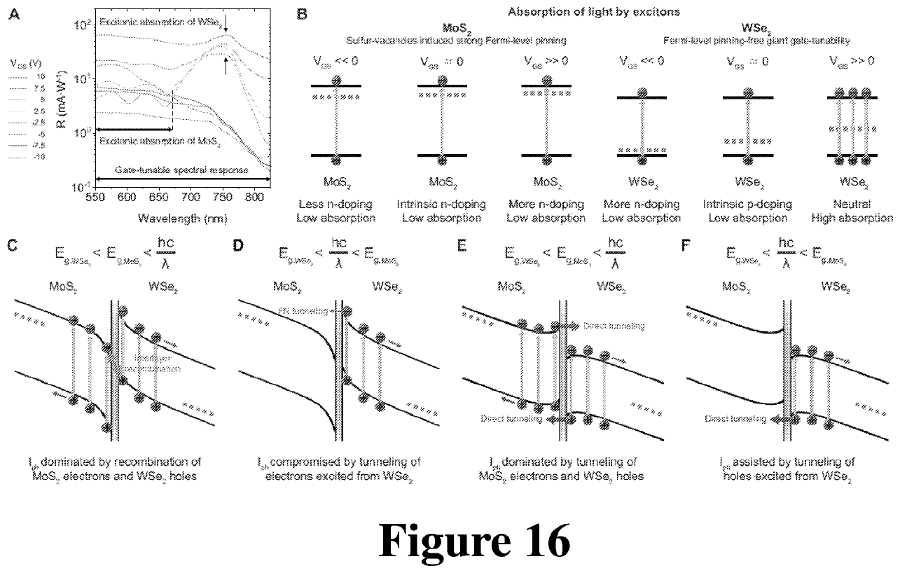

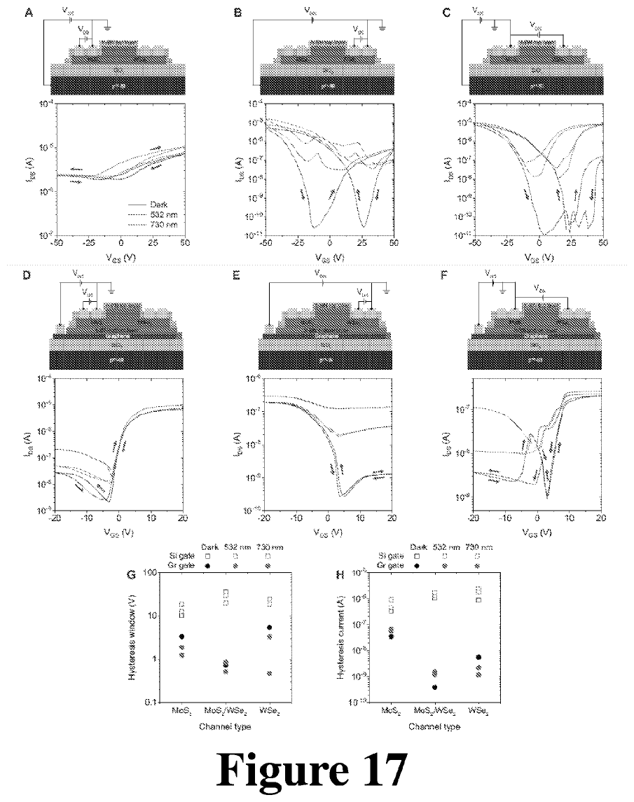

measured at different V_{GS} and incident light wavelengths is used to encode the spectral response matrix, where the photocurrent is defined as Iₚₕ=I_{light}−I_{dark}, with I_{light} and I_{dark} representing I_{DS} with and without light illumination at V_{DS}=3 V, respectively, and P is the incident light power (FIG. 12). The gate-tunable spectral response with high sensitivity over a wide spectral range is due to the wavelength-dependent absorption (29) of MoS₂ and WSe₂ as well as the controllable charge carrier transport (22-28) through the MoS₂/WSe₂ interface, unlike the individual material. The spectral response matrix (FIG. 2D) inherits a rich structure from the dynamics of photoexcited charge carriers generated across the tunable MoS₂/WSe₂ heterojunction (22-29), confirming fast and stable spectral detection with giant gate-tunability in our MoS₂/WSe₂ heterojunction (FIGS. 13, 14, 15, 16, and 17).

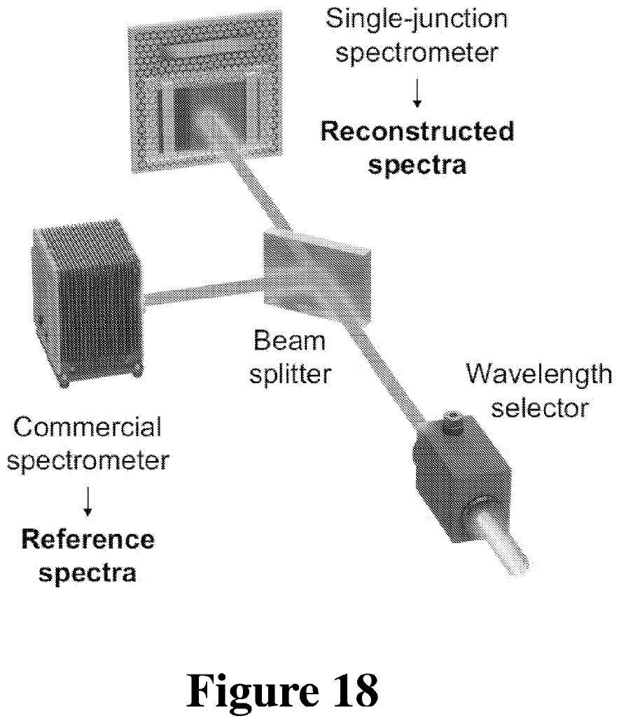

After encoding this spectral response matrix (FIG. 2D) for the learning process, our single-junction spectrometer is ready to measure unknown incident light spectra, following the workflow diagram (FIG. 6). Briefly, we measure the gate-tunable photocurrent of the unknown incident light and then compute its constrained least-square solution to reconstruct the spectrum using adaptive Tikhonov regularization by minimizing the residual norm with a regularization factor (1, 8). Details of the optical setup and computational reconstruction are provided in FIG. 18, sections MM3 and MM4.

The quasi-monochromatic and complex broadband spectra reconstructed with our single-junction spectrometer agree well with the reference spectra measured using a commercial spectrometer, demonstrating the viability of our single-junction spectrometer concept (FIGS. 2, E and F). Note that, while the demonstrated spectrometer bandwidth (from ~405 to 845 nm) is limited due to the availability of the light wavelengths in our laboratory, the MoS₂/WSe₂ heterojunction exhibits photoresponse from ~400 to 2400 nm (25). Indeed, the vdW junctions are known to exhibit photodetection capability for incident light whose wavelength corresponds to around half (or even much smaller than) the bandgap of each material (15-17, 25). Therefore, in principle, our single-junction spectrometer is not limited by the material bandgap and likely offers operation bandwidth broader than our demonstration. Our single-junction spectrometer using the interlayer transport mediated photoresponse is fundamentally different from the previously demonstrated spectrometer concepts, such as bandgap engineering and grading (7-10).

To evaluate deviations between the reconstructed and reference spectra, the peak signal-to-noise ratio (PSNR) has previously been used to analyze the mean squared error (section ST2). The maximum PSNR estimated from the extrapolation is ~35.7 and 33.6 dB for the quasi-monochromatic and complex broadband spectra, respectively (FIG. 2G). A reasonable learning step (i.e. step in wavelength for encoding the spectral response matrix) can be chosen based on the saturated PSNR. Therefore, a high-speed learning process is achievable with a large learning step and slightly reduced accuracy (11).

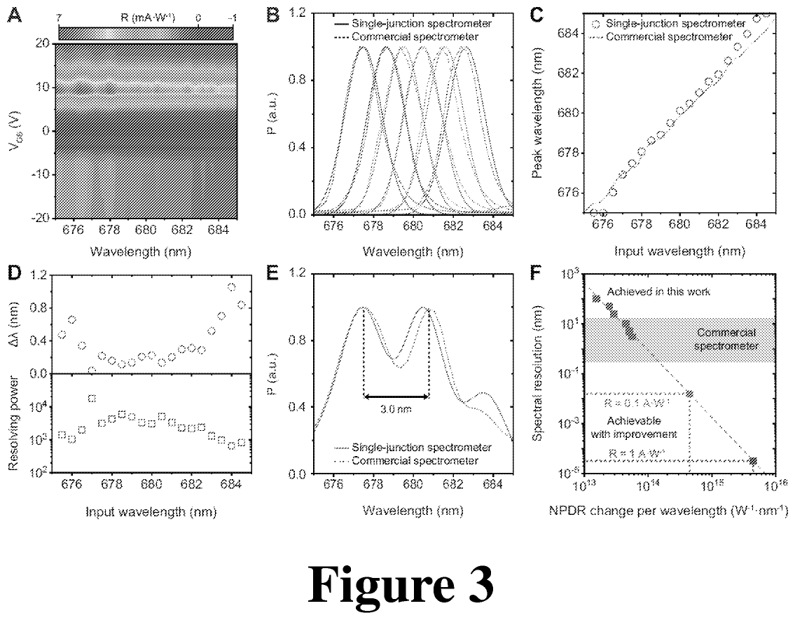

The wavelength resolving power is an important measure of spectrometers in practical applications (1, 2). To demonstrate high spectral resolution capability with our single-junction ultra-miniaturized spectrometer, we construct a high-density spectral response matrix through an ultra-small learning step of ~0.1 nm using monochromatic light from ~675 nm to 685 nm for the learning process (FIG. 3A). Our single-junction spectrometer encoded by the high-density spectral response matrix can resolve monochromatic light with high accuracy (FIGS. 3, B and C). The average peak wavelength difference (Δλ) between reconstructed and reference spectra is ~0.36±0.06 nm, with a minimum of ~0.04 nm (FIG. 3D). This is comparable to the learning step of ~0.1 nm. The wavelength resolving power

$$( {R}_{λ} = \frac{λ}{Δ λ} )$$

at a given input wavelength (λ) is ~3470±880.

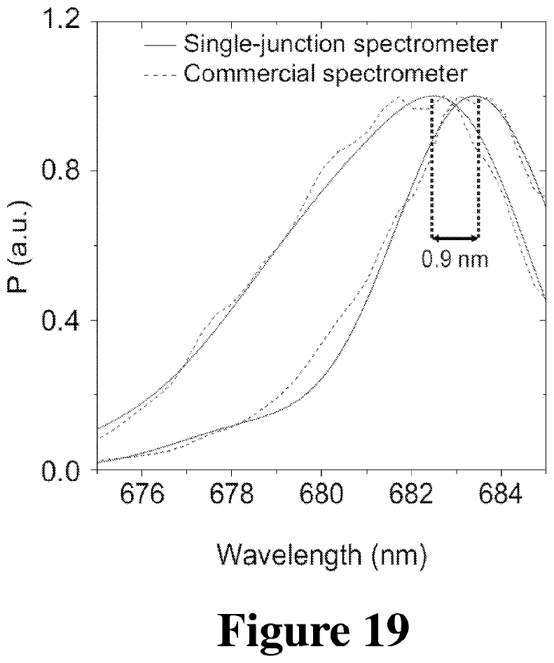

Furthermore, we measure complex incident spectra to study spectral resolution. Two peaks at ~679 nm, separated by ~3 nm, are successfully distinguished (FIG. 3E). Our spectrometer can also resolve broadband spectra and identify their peak wavelengths with high resolution (~0.9 nm demonstrated in FIG. 19). This indicates that our spectrometer has spectral resolution comparable to or better than the current state-of-the-art miniaturized spectrometers (1-11) with footprint (~22×8 μm²) comparable to or smaller than most. This is several orders of magnitude smaller than commercial miniaturized spectrometers (30) and recently demonstrated spectrometers with metasurfaces (4), quantum dots (6), or a single-dot perovskite (10); see FIG. 21 for a detailed comparison. We note that the demonstrated accuracy (~0.36 nm) and resolution (~3 nm), which are limited by the smallest incident wavelength step available in our laboratory, can be further improved by minimizing the learning step during the learning process. We suggest that such a learning process is practical for applications, similar to the calibration process in traditional spectrometers.

Many strategies can be considered to improve the resolution, accuracy, and speed of our single-junction spectrometer (1). These include: (A) increasing the dataset size to create higher density spectral response matrix by minimizing the learning step (7-11), (B) designing junctions with higher response and larger wavelength or gate dependence (15-17), and (C) optimizing the reconstruction algorithm (e.g., suppressing the perturbation with more advanced regularization (1, 8) or increasing the accuracy with convolutional processing (20, 21)). Ideally, decreasing the learning step is a straightforward approach to form a denser spectral response matrix for more accurate spectral reconstruction. However, there is a trade-off: signal difference, measured at small learning steps, comparable to the measurement noise could result in errors during reconstruction.

The higher the photoresponsivity, the more advantageous it is to distinguish the wavelength dependent photoresponse at different V_{GS}. More specifically, high gradience of the spectral response matrix component is required to yield a high spectral resolution (1,6-11). To illustrate the future development possibilities of single-junction spectrometers, we consider the normalized photocurrent-to-dark current ratio (NPDR) change per wavelength step of two resolved peaks (section ST3). The extrapolated line in FIG. 3F indicates the potential of our approach with improved photoresponsivity for higher resolution than the commercial miniaturized spectrometers (30). The achievable resolution is highlighted based on recently reported photoresponse (~0.1 to 1 A·W⁻¹ at 532 nm) of MoS₂/WSe₂ heterojunctions (25). The resolution and bandwidth can be further improved by engineering junctions with different combinations of various 2D materials or integrating waveguides (15-17). Additional strategies for improving performance are provided in section ST4. With a significant potential to improve performance, our single-junction spectrometer can not only be adapted to other tunable junction architectures but also integrated with CMOS (complementary metal-oxide-semiconductor)-compatible platforms.

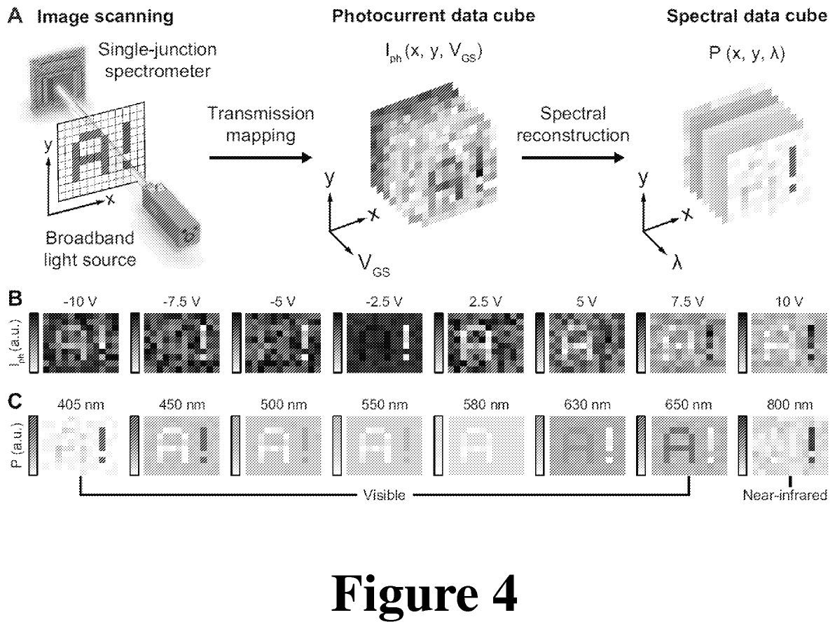

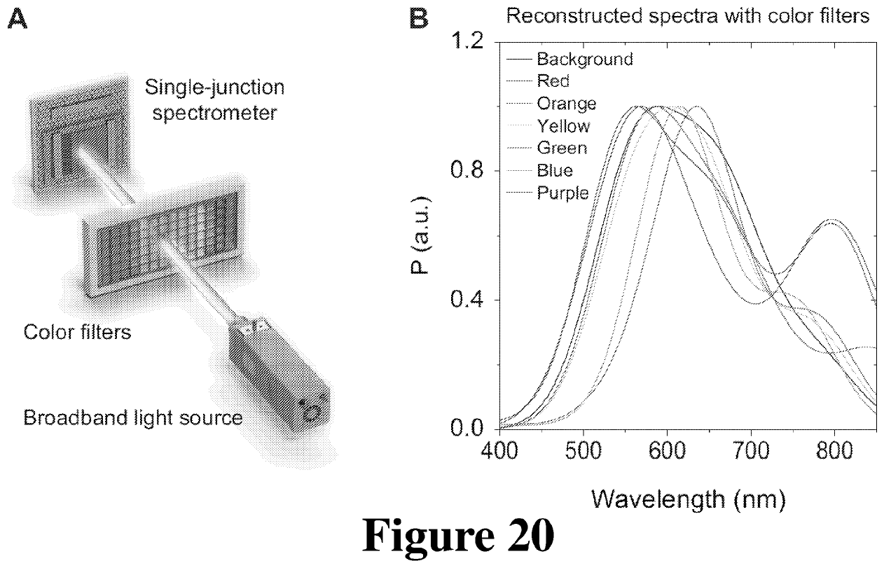

Our single-junction spectrometer can benefit from the recently developed large-scale 2D material synthesis to construct an array for future spectral imaging. Here, we demonstrate proof-of-concept spectral imaging of a color filter consisting of red, blue, and transparent areas with spatial scanning using our spectrometer (FIG. 4A). At each mapping position, the measured photocurrent data at different V_{GS} are recorded in the spatial response data cube for spectral reconstruction. A series of photocurrent mapping data scanned at different V_{GS} is displayed (FIG. 4B) and converted to a series of spectral data reconstructed at different wavelengths (FIG. 4C). The spectral images indicate that the red and blue filters absorb more incident broadband light from ~405 to 580 nm, and from ~600 to 700 nm, respectively. As a result, the spectra of the red uppercase alphabet “A” (from ~450 to 700 nm) and the blue exclamation mark “!” (from 405 to 845 nm) are distinguishable from that of the background. Note that a strong light signal at near 800 nm for the exclamation mark “!” can be fully detected, highlighting the advantages of spectral imaging over conventional RGB color imaging (FIG. 20 with different color filters). In our demonstration, the image resolution is defined by the mapping step. However, our concept has great potential for large-scale spectral imaging by future array devices, offering high spatial resolution with the junction at the micrometer- or nanometer-scale.

We have demonstrated a high-performance ultra-miniaturized spectrometer using a single vdW-junction. In our spectrometer concept, no photodetector array, filter array, or other bulky dispersive components are required to achieve high resolution, sub-nm accuracy, and broad operation bandwidth. The ultra-compact footprint of our single-junction spectrometers may provide scalability and compatibility with the current photonic integrated circuits and CMOS-compatible processes for direct integration into modern smartphones, lab-on-a-chip systems, and other customized devices ranging from bio-implants to drones and satellites.

### MM1: Device Fabrication and Characterization.

Our single-junction spectrometers were fabricated by assembling graphene, MoS₂, WSe₂, and h-BN into vdW heterostructures flake by flake. Here we adopted semi-dry transfer method (31-33) using Kapton tape for graphene and dry-release transfer method (34-36) using polypropylene carbonate and polydimethylsiloxane membranes for MoS₂, WSe₂, and h-BN. The monolayer graphene grown by chemical vapor deposition from Graphenea was transferred onto highly doped Si substrates with a 285 nm thick SiO₂ layer preprocessed with solvent cleaning. The graphene layer was patterned with electron beam lithography (EBL, Vistec EBPG 5000) and dry-etched with reactive ion etching (RIE, Oxford Instruments PlasmaLab 80 Plus) to define each sample electrically isolated from each other. The MoS₂, WSe₂, and h-BN flakes were mechanically exfoliated from their bulk single crystals (2D Semiconductors). The h-BN flakes were placed deterministically onto each graphene gate to control the portion of the covered and uncovered regions. The WSe₂ and MoS₂ flakes were subsequently transferred onto the h-BN-covered graphene. All electrodes and pads were patterned with EBL and deposited through electron beam evaporation (MASA IM-9912), followed by a lift-off process. Note that Ti/Au (10/50 nm) and Pd/Au (10/50 nm) electrodes were used to facilitate electron (hole) injection in MoS₂ (WSe₂) (22-28). As a passivation layer, additional h-BN flakes were transferred to encapsulate the MoS₂ and WSe₂ flakes to prevent the surface modification from the adhesion of gas or water molecules. After device fabrication, the h-BN/MoS₂/WSe₂/h-BN/graphene vdW heterostructures were characterized (FIG. 7) by optical microscopy (Olympus BX60 and MX63L), atomic force microscopy (AFM, Bruker Dimension Icon) using tapping mode, and Raman spectroscopy (WITec Alpha 300 RA+) using a 532 nm continuous wave laser source.

### MM2: Optical Setup.

A spectrally filtered supercontinuum laser source (SuperK Extreme, NKT Photonics) was used to photoexcite charge carriers in the heterostructures. The spectral bandwidth of this light source was controlled either by a tunable spectral filter (SuperK Varia, NKT Photonics), or by a grating-based monochromator (Andor Shamrock 750, with a Silver coated grating of 600 lines/mm and 1200 nm blaze). Note that the tunable spectral filter allows for controlling the spectral bandwidth from ~10 nm (FIG. 2E) up to ~100 nm, while the grating-based monochromator allows for obtaining a spectral bandwidth of ~2 nm with the peak wavelength step of ~0.1 nm (FIG. 3B). The spectrally filtered laser source was measured by a commercial spectrometer (OceanOptics, Flame VIS) for reference. The laser beam was guided and completely focused onto the heterojunction of single-junction spectrometers using an objective lens (Mitutoyo, 50× Plan Apo NIR Infinity corrected, NA 0.2) that allows for a spot size of from 1 to 2 μm. The schematic diagram of the optical setup is depicted in FIG. 4 and FIG. 18.

### MM3: Electrical and Optoelectrical Measurements.

The fabricated device chips were wire-bonded to custom-designed printed circuit boards fitted to our optical setup. The homebuilt optical system allowed us to focus the laser beam on desired positions. All the electrical and optoelectrical measurements were carried out in our home-built optical system combined with two source meters (Keithley 2400 and 2401) under ambient conditions. The source, drain, and gate electrodes are connected to the MoS₂, WSe₂, and graphene, respectively. The gate-source voltage V_{GS} is applied across graphene (37,38) and MoS₂, while the drain-source voltage V_{DS} is applied across WSe₂ and MoS₂. To reduce the measurement noise according to the sweep direction, V_{GS} was always swept from 0 to 20 V (or 30 V) and −20 V (or −30 V) and then swept back to 0 V. All measurements are repeated more than three times to confirm the reproducibility.

### MM4: Computational Reconstruction.

The reconstruction algorithm obtains an unknown spectrum of the incident light on our single-vdW-junction spectrometer based on the spectral response matrix encoded with multiple known monochromatic light in the learning process and the measured response data in the testing process (1, 6-11). In the reconstruction process, the measured response data corresponds to the photocurrent dataset through the integration of an unknown spectrum function and the spectral response matrix over the wavelength range. To extract an unknown spectrum, the set of wavelength-independent weight coefficients should be determined for the linear expansion of the spectrum with simple basis functions. The basis function for the linear expansion of the spectrum is chosen as the Gaussian function. Note that discretization of the integral formula that combines the unknown spectral function, response matrix, and photocurrent data allows the expression of the integral formula in the form of a system of linear equations. In the given matrix form, the residual norm (squared error) must be minimized by solving the non-negative least-square problem. A direct minimization of the residual norm leads to the instabilities in the solution due to the high-frequency noise signals. To address this issue, the Tikhonov regularization is used in our code to stabilize the minimization procedure. In this approach, an auxiliary term, defined by the regularization factor (damping coefficient), is added to the residual norm. This regularization factor should be chosen properly to satisfy conditions of robustness and reflect the signal noise level. The generalized cross-validation adaptive method is used to find the optimal value of the regularization factor. A vector of coefficients that provides a global minimum of the modified residual norm enables the reconstruction of an unknown spectrum with substitution of it in the initial expansion in basis functions. All spectra reconstructed with our spectrometer and measured with a commercial spectrometer are normalized with maximum intensities. More details are provided in FIG. 6.

### ST1: Spectrometer Miniaturization Strategy

Most conventional spectrometers rely on the dispersive components and detector or filter arrays (3-5, 39-41). Some dispersive components can be stacked vertically, but detectors or filters cannot (1,2). Therefore, for the ultimate spectrometer miniaturization, the array structure must be minimized, and it is best to implement the spectrometer with a single detector.

The tunable wavelength-dependent photoresponse is the most important key parameter for the performance of miniaturized computational spectrometers (1, 6-11). However, in the case of methods that rely on material bandgap, their spectral resolution and bandwidth are typically restricted by the number of integrated detectors (6-8) or bandgap modulation limits (9,10). For example, the spectrometers using multiple nanowires (7) or a bandgap-graded single-nanowire (8) requires a photodetector array for their demonstrated resolutions. Each nanowire channel with a different bandgap represents a single detector with a different filter, which requires the detector array and limits the further reduction in footprint. On the other hand, the single-detector spectrometers reported so far (9-11) are limited by their performance: ~90 nm resolution (9) and usability: cryogenic operational requirements (11) due to the insufficient tunability in the spectral response.

In contrast, a vdW junction exhibit a tunable spectral response with high sensitivity over a wide spectral range owing to the controllable and unique interlayer transport. vdW junctions can be also stacked vertically with different bandgaps to minimize the spectrometer footprint. As listed in FIG. 21 (3-11, 39-41), our single-vdW-junction spectrometer can achieve higher performance than other computational spectrometers in ambient conditions (6-11).

### ST2: Peak Signal-to-Noise Ratio

The deviations between spectra reconstructed with our single-junction spectrometer (S_{rec}) and measured with a commercial spectrometer (S_{ref}) are evaluated with the peak signal-to-noise ratio (PSNR). All reconstructed (S_{rec}) and reference (S_{ref}) spectra are first normalized with maximum intensities. As expressed in the equation below, the PSNR is defined with the mean squared error (MSE), where MAX is the maximum possible value of the spectra (11).

$$MSE = \frac{1}{N} {\sum }_{n = 1}^{N} {[ {S}_{sec} ( {λ}_{n} ) - {S}_{ref} ( {λ}_{n} ) ]}^{2}$$

The spectral or peak wavelength accuracy of the reconstructed spectra highly depends on the number of sampling elements encoded in the spectral response matrix. We introduce the learning step defined by the wavelength step used during the learning process (11). We set the wavelength learning step as ~25 nm that is used to reconstruct the spectra of FIGS. 2, E and F. The increased learning step represents fewer wavelength sampling elements by increasing the wavelength step (FIG. 2G). The maximum PSNR estimated from the extrapolation in FIG. 2G is ~35.7 and 33.6 dB for the quasi-monochromatic and complex broadband spectra, respectively. In our case, our spectral response matrix is constructed with monochromatic light during the learning process. Therefore, more accurate reconstruction is easily achievable for the quasi-monochromatic spectra with a larger learning step than the complex broadband spectra.

### ST3: Future Prospect of Single-vdW-Junction Spectrometers

Our single-vdW-junction spectrometer represents single-detector spectral measurement by engineering the spectral response via electrical tuning. This dispersion-free, filter-free, and detector-array-free computational spectrometer concept provides the ultimate miniaturization strategy. Unlike commonly employed computational spectrometers that rely on the detector array (6-8), the resolution and accuracy of the single-detector spectrometers (9-11) are highly dependent on the performance of the detector. Note that encoding the spectral response matrix of the single-junction spectrometer can be a similar process to calibrating the grating angles in traditional commercial spectrometers by measuring the spectrum with incident wavelengths that are already known. In general, high-performance spectrometers should display spectra with high resolution and high accuracy. For the computational spectrometers, high photoresponsivity can lead to high performance, but not always, since the photoresponsivity is normalized in the reconstruction algorithm. Therefore, the variability of their photoresponsivity at different V_{GS} and incident light wavelengths is an important factor. In that sense, our single-vdW-junction spectrometer can offer the ultimate miniaturization with unprecedented performance. Here, we estimate spectral resolution using our single-junction spectrometer concept as a function of the average normalized photocurrent-to-dark current ratio (NPDR) change per wavelength spacing of two resolved peaks, which can be obtained with the spectral response matrix. The future development of ultra-high-resolution single-vdW-junction spectrometers is predicted (FIG. 3F) with the extrapolated line (15-17, 22-28, 42-45). Based on the expected development, the single-junction spectrometer concept can be used to aim for ultra-high-resolution superior to the commercial high-resolution spectrometer.

### ST4: Performance Improvement Strategies

In general, rational design of vdW junction interfaces aiming towards other unique bandgap contrasts or alignments may further enhance the resolution and broaden the bandwidth (15-17). An advanced programming scheme could be also adopted into the reconstruction algorithm to enhance the spectrometer performance.

Detailed strategies to improve the performance of single-junction spectrometer concept are as follows: increasing the variety of wavelength-dependent photoresponse with (A) tunable interlayer transport across other vdW junction interfaces (15-17, 42-45); (B) tunable internal photoemission via Schottky barrier height modulation (46-49); (C) hybrid/switchable/negative photoresponse (50-52); (D) vertical vdW heterostructures stacking or superlattices (53-55); (E) large-area array integration (56-59), or upgrading the reconstruction algorithm with (F) convolutional processing or other deep learning algorithms (20,21,60); (G) other basis functions for the linear expansion (1, 8).

### INDUSTRIAL APPLICABILITY

At least some embodiments of the present invention find industrial application in spectrometry.

### Acronyms List

AFM atomic force microscopy
CMOS complementary metal-oxide-semiconductor
EBL electron beam lithography
FN Fowler-Nordheim
MSE mean squared error
NPDR normalized photocurrent-to-dark current ratio
PSNR peak signal-to-noise ratio
RIE reactive ion etching
V_{DS} drain-source voltage
V_{GS} gate-source voltage
vdW van der Waals

REFERENCE SIGNS LIST

| | |
|---|---|
| 110 | MoS₂ |
| 120 | WSe₂ |
| 130 | SiO₂ |
| 140 | p⁺⁺-Si, |
| 150 | h-BN bottom layer |
| 160 | Graphene |
| 170 | h-BN top layer |
| 180 | gate-source voltage connection |
| 181 | Additional electrode on MoS₂ |
| 182 | gate-source/drain-source voltage connection |
| 183 | drain-source voltage connection |
| 184 | Additional electrode on WSe₂ |

### CITATION LIST

### Non Patent Literature

1. Z. Yang, T. Albrow-Owen, W. Cai, T. Hasan, Miniaturization of optical spectrometers. Science 371, eabe0722 (2021).
2. R. F. Wolffenbuttel, State-of-the-art in integrated optical microspectrometers. IEEE Trans. Instrum. Meas. 53, 197-202 (2004).
3. Z. Wang et al., Single-shot on-chip spectral sensors based on photonic crystal slabs. Nat. Commun. 10, 1020 (2019).
4. A. Tittl et al., Imaging-based molecular barcoding with pixelated dielectric metasurfaces. Science 360, 1105-1109 (2018).
5. D. M. Kita et al., High-performance and scalable on-chip digital Fourier transform spectroscopy. Nat. Commun. 9, 4405 (2018).
6. J. Bao, M. G. Bawendi, A colloidal quantum dot spectrometer. Nature 523, 67-70 (2015).
7. J. Meng, J. J. Cadusch, K. B. Crozier, Detector-only spectrometer based on structurally colored silicon nanowires and a reconstruction algorithm. Nano Lett. 20, 320-328 (2019).
8. Z. Yang et al., Single-nanowire spectrometers. Science 365, 1017-1020 (2019).
9. S. Yuan, D. Naveh, K. Watanabe, T. Taniguchi, F. Xia, A wavelength-scale black phosphorus spectrometer. Nat. Photonics 15, 601-607 (2021).
10. L. Guo et al., A single-dot perovskite spectrometer. Adv. Mater., 2200221 (2022).
11. L. Kong et al., Single-detector spectrometer using a superconducting nanowire. Nano Lett 21, 9625-9632 (2021).
12. F. Xia, T. Mueller, Y.-m. Lin, A. Valdes-Garcia, P. Avouris, Ultrafast graphene photodetector. Nat. Nanotechnol. 4, 839-843 (2009).
13. M. Buscema et al., Photocurrent generation with two-dimensional van der Waals semiconductors. Chem. Soc. Rev. 44, 3691-3718 (2015).
14. F. Koppens et al., Photodetectors based on graphene, other two-dimensional materials and hybrid systems. Nat. Nanotechnol. 9, 780-793 (2014).
15. A. K. Geim, I. V. Grigorieva, Van der Waals heterostructures. Nature 499, 419-425 (2013). 16. M. M. Furchi, A. Pospischil, F. Libisch, J. Burgdörfer, T. Mueller, Photovoltaic effect in an electrically tunable van der Waals heterojunction. Nano Lett. 14, 4785-4791 (2014).
17. N. Ubrig et al., Design of van derWaals interfaces for broad-spectrum optoelectronics. Nat. Mater. 19, 299-304 (2020).
18. S. Wang et al., Nonvolatile van der Waals heterostructure phototransistor for encrypted optoelectronic logic circuit. ACS Nano 16, 4528-4535 (2022).
19. Y. Sun, Y. Ding, D. Xie, Mixed-dimensional van der Waals heterostructures enabled optoelectronic synaptic devices for neuromorphic applications. Adv. Funct. Mater. 31, 2105625 (2021).
20. S. Lee, R. Peng, C. Wu, M. Li, Programmable black phosphorus image sensor for broadband optoelectronic edge computing. Nat. Commun. 13, 1485 (2022).
21. L. Pi et al., Broadband convolutional processing using band-alignment-tunable heterostructures. Nat. Electron. 5, 248-254 (2022).
22. C.-H. Lee et al., Atomically thin p-n junctions with van der Waals heterointerfaces. Nat. Nanotechnol. 9, 676-681 (2014).
23. T. Roy et al., Dual-gated MoS2/WSe2 van der Waals tunnel diodes and transistors. ACS Nano 9, 2071-2079 (2015).
24. A. Nourbakhsh, A. Zubair, M. S. Dresselhaus, T. Palacios, Transport properties of a MoS2/WSe2 heterojunction transistor and its potential for application. Nano Lett. 16, 1359-1366 (2016).
25. M. Long et al., Broadband photovoltaic detectors based on an atomically thin heterostructure. Nano Lett. 16, 2254-2259 (2016).
26. Y. Son et al., Observation of switchable photoresponse of a monolayer WSe2-MoS2 lateral heterostructure via photocurrent spectral atomic force microscopic imaging. Nano Lett. 16, 3571-3577 (2016).
27. M.-H. Doan et al., Charge transport in MoS2/WSe2 van der Waals heterostructure with tunable inversion layer. ACS Nano 11, 3832-3840 (2017).
28. X. Sun et al., Visualizing Band Profiles of Gate-Tunable Junctions in MoS2/WSe2 Heterostructure Transistors. ACS Nano 15, 16314-16321 (2021).
29. H. S. Ra et al., An Asymmetry Field-Effect Phototransistor for Solving Large Exciton Binding Energy of 2D TMDCs. Adv. Mater. 34, 2107468 (2022).
30. Mini-spectrometers product lineup (Hamamatsu, 2022); https://www. hamamatsu.com/eu/en/product/optical-sensors/spectrometers/mini-spectrometer.html
31. H. H. Yoon et al., Strong fermi-level pinning at metal/n-Si (001) interface ensured by forming an intact Schottky contact with a graphene insertion layer. Nano Lett. 17, 44-49 (2017).
32. S. Jung et al., Reduction of water-molecule-induced current-voltage hysteresis in graphene field effect transistor with semi-dry transfer using flexible supporter. J. Appl. Phys. 125, 184302 (2019).
33. H. H. Yoon et al., Negative Fermi-level pinning effect of metal/n-GaAs (001) junction induced by a graphene interlayer. ACS Appl. Mater. Interfaces 11, 47182-47189 (2019).
34. F. Pizzocchero et al., The hot pick-up technique for batch assembly of van der Waals heterostructures. Nat. Commun. 7, 11894 (2016).
35. R. Frisenda et al., Recent progress in the assembly of nanodevices and van der Waals heterostructures by deterministic placement of 2D materials. Chem. Soc. Rev. 47, 53-68 (2018).
36. K. Kinoshita et al., Dry release transfer of graphene and few-layer h-BN by utilizing thermoplasticity of polypropylene carbonate. npj 2D Mater. Appl. 3, 22 (2019).
37. L. Britnell et al., Field-effect tunneling transistor based on vertical graphene heterostructures. Science 335, 947-950 (2012).
38. F. Ahmed et al., Dielectric dispersion and high field response of multilayer hexagonal boron nitride. Adv. Funct. Mater. 28, 1804235 (2018).
39. M. Faraji-Dana et al., Compact folded metasurface spectrometer. Nat. Commun. 9, 4196 (2018).
40. E. Le Coarer et al., Wavelength-scale stationary-wave integrated Fourier-transform spectrometry. Nat. Photonics 1, 473-478 (2007).
41. H. Sun et al., In situ formed gradient bandgap-tunable perovskite for ultrahighspeed color/spectrum-sensitive photodetectors via electron-donor control. Adv. Mater. 32, 1908108 (2020).
42. Y. Liu et al., Van der Waals heterostructures and devices. Nat. Rev. Mater. 1, 16042 (2016). 43. K. Novoselov, o. A. Mishchenko, o. A. Carvalho, A. Castro Neto, 2D materials and van der Waals heterostructures. Science 353, aac9439 (2016).
44. D. Jariwala, T. J. Marks, M. C. Hersam, Mixed-dimensional van derWaals heterostructures. Nat. Mater. 16, 170-181 (2017).
45. G. Konstantatos, Current status and technological prospect of photodetectors based on twodimensional materials. Nat. Commun. 9, 5266 (2018).
46. L. Pahun, Y. Campidelli, F. A. d'Avitaya, P. Badoz, Infrared response of Pt/Si/ErSil:7 heterostructure: tunable internal photoemission sensor. Appl. Phys. Lett. 60, 1166-1168 (1992).
47. P. Vabbina et al., Highly sensitive wide bandwidth photodetector based on internal photoemission in CVD grown p-type MoS2/graphene Schottky junction. ACS Appl. Mater. Interfaces 7, 15206-15213 (2015).
48. H. Yang et al., Graphene barristor, a triode device with a gate-controlled Schottky barrier. Science 336, 1140-1143 (2012).
49. Y. J. Choi et al., Color-selective Schottky barrier modulation for optoelectric logic. ACS Nano 14, 16036-16045 (2020).
50. H. H. Yoon et al., Tunable Quantum Tunneling through a Graphene/Bi2Se3 Heterointerface for the Hybrid Photodetection Mechanism. ACS Appl. Mater. Interfaces 13, 58927-58935 (2021).
51. M. Du et al., Switchable photoresponse mechanisms implemented in single van der Waals semiconductor/metal heterostructure. ACS Nano 16, 568-576 (2022). 52. X. Bai et al., Molybdenum disulfide/double-wall carbon nanotube mixed-dimensional heterostructures. Adv. Mater. Interfaces 9, 2200193 (2022).
53. N. Li et al., van der Waals semiconductor empowered vertical color sensor. ACS Nano 16, 8619-8629 (2022).
54. G. Jin et al., Heteroepitaxial van der Waals semiconductor superlattices. Nat. Nanotechnol. 16, 1092-1098 (2021).
55. W. Zhang, Q. Wang, Y. Chen, Z. Wang, A. T. Wee, Van der Waals stacked 2D layered materials for optoelectronics. 2d Mater. 3, 022001 (2016).
56. S. Goossens et al., Broadband image sensor array based on graphene-CMOS integration. Nat. Photonics 11, 366-371 (2017).
57. W. Liu et al., Graphene charge-injection photodetectors. Nat. Electron. 5, 281-288 (2022).
58. C. Gong et al., 2D nanomaterial arrays for electronics and optoelectronics. Adv. Funct. Mater. 28, 1706559 (2018).
59. J. Li et al., General synthesis of two-dimensional van der Waals heterostructure arrays. Nature 579, 368-374 (2020).
60. L. Mennel et al., Ultrafast machine vision with 2D material neural network image sensors. Nature 579, 62-66 (2020).
61. C. Kim et al., Fermi level pinning at electrical metal contacts of monolayer molybdenum dichalcogenides. ACS Nano 11, 1588-1596 (2017).
62. J. Jang et al., Fermi-Level Pinning-Free WSe2 Transistors via 2D van der Waals metal contacts and their circuits. Adv. Mater. 34, 2109899 (2022).
63. X. Liu, M. S. Choi, E. Hwang, W. J. Yoo, J. Sun, Fermi level pinning dependent 2D semiconductor devices: challenges and prospects. Adv. Mater. 34, 2108425 (2022).
64. J. Xiao, M. Zhao, Y. Wang, X. Zhang, Excitons in atomically thin 2D semiconductors and their applications. Nanophotonics 6, 1309-1328 (2017).
65. M. Massicotte et al., Dissociation of two-dimensional excitons in monolayer WSe2. Nat. Commun. 9, 1633 (2018).

1. A spectrometer comprising:
a layer of molybdenum disulphide and a layer of tungsten diselenide forming a van der Waals heterojunction therebetween, the layer of molybdenum disulphide partly overlapping the layer of tungsten diselenide;
a first hexagonal boron nitride layer below the heterojunction, facing the layer of tungsten diselenide and a part of the layer of molybdenum disulphide;
a second hexagonal boron nitride layer above the heterojunction, covering the layers of molybdenum disulphide and tungsten diselenide;
a monolayer graphene film below the first hexagonal boron nitride layer, and
an electrical connection, provided with a tunable gate-source voltage source and a tunable drain-source voltage source, connecting a gate electrode connected to the monolayer graphene film to a source electrode connected to the layer of molybdenum disulphide and to a drain electrode connected to the layer of tungsten diselenide.

2. The spectrometer according to claim 1, wherein the spectrometer comprises only a single van der Waals junction.

3. The spectrometer according to claim 1, configured to determine a wavelength of radiation incident on the spectrometer based on a spectral response matrix and a gate-source voltage value.

4. The spectrometer according to claim 1, configured to determine a spectrum of radiation incident on the spectrometer based on a spectral response matrix and tuneable photocurrent values of the heterojunction, the tunability of the photocurrent values of the heterojunction being obtained by changing gate-source voltage values.

5. The spectrometer according to claim 1, wherein the layer of tungsten diselenide is partly between the layer of molybdenum disulphide and the first hexagonal boron nitride layer.

6. The spectrometer according to claim 1, wherein a footprint size of the spectrometer is 22×8 square micrometres.

7. The spectrometer according to claim 1, wherein the spectrometer does not comprise a photodetector array or a filter array.

8. The spectrometer according to claim 1, further comprising a silicon oxide layer attached to a side of the monolayer graphene film which does not face the first hexagonal boron nitride layer.

9. The spectrometer according to claim 8, further comprising a silicon substrate attached to the silicon oxide layer.
